(19) United States
(12) Patent Application Publication
(10) Pub. No.: US 2018/0228055 A1
(43) Pub. Date: Aug. 9, 2018

(54) ELECTRONIC APPARATUS

(71) Applicant: FUJITSU LIMITED, Kawasaki-shi (JP)

(72) Inventors: Takahisa Yoshizumi, Fukuoka (JP); HAYAMI ABE, Yokohama (JP); Akira MATSUO, Kawasaki (JP); Kazunori Omori, Kasuga (JP)

(73) Assignee: FUJITSU LIMITED, Kawasaki-shi (JP)

(21) Appl. No.: 15/867,368

(22) Filed: Jan. 10, 2018

(30) Foreign Application Priority Data
Feb. 6, 2017 (JP) 2017-019695

(51) Int. Cl. H05K 7/20; F04B 23/02; F04B 49/02; H05K 7/18

(52) U.S. Cl. CPC H05K 7/20272; F04B 23/02; H05K 7/20781; H05K 7/18; F04B 49/02

(57) ABSTRACT

An electronic apparatus includes a reservoir tank that stores a liquid refrigerant, a pump, a pump-lowering parts that allows the pump to be lowered to a position that is lower than the reservoir tank, and a first flow path member that is coupled between the reservoir tank and the pump, and is flexible.

### CROSS-REFERENCE TO RELATED APPLICATION

This application is based upon and claims the benefit of priority of the prior Japanese Patent Application No. 2017-19695, filed on Feb. 6, 2017, the entire contents of which are incorporated herein by reference.

### FIELD

The present disclosure relates to an electronic apparatus.

### BACKGROUND

A technique is known in which a reservoir tank is installed at a higher position than a pump.

However, in this technique of the related art, when it is not possible to install the reservoir tank at a position that is sufficiently higher than the pump, it is difficult to start the pump without moving the installation position of the reservoir tank. In an electronic apparatus, it may not be possible to install the reservoir tank at a position that is sufficiently higher than the pump due to layout restrictions or demands for size reduction and so forth. In such a case, although it may be possible to start the pump if the reservoir tank is temporarily moved to a higher position by detaching the reservoir tank, for example, this is inconvenient in that the work of detaching the reservoir tank and the subsequent installation work is complex.

The followings are reference documents.

### [Document 1] Japanese Laid-open Patent Publication No. 2006-201987,

### [Document 2] Japanese Laid-open Patent Publication No2003-229526, and

### [Document 3] Japanese Laid-open Patent Publication No2004-163007.

### SUMMARY

According to an aspect of the invention, an electronic apparatus includes a reservoir tank that stores a liquid refrigerant, a pump, a pump-lowering parts that allows the pump to be lowered to a position that is lower than the reservoir tank, and a first flow path member that is coupled between the reservoir tank and the pump, and is flexible.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a front view illustrating an electronic apparatus according to embodiment 1;

FIG. 2 is a perspective view illustrating a water cooling unit and a bookshelf-type apparatus;

FIG. 3 is an explanatory diagram of an overview of a cooling system in an electronic apparatus;

FIG. 4 is a plan view of a water cooling unit;

FIG. 5 is a diagram illustrating a cross section taken along line V-V in FIG. 4 and illustrates members on the side of the line V-V indicated by the arrows;

FIG. 6 is a plan view for explaining a movement mode of a pump attachment plate;

FIG. 7 is a diagram illustrating a cross section taken along line VII-VII in FIG. 6, and illustrates members on the side of the line VII-VII indicated by the arrows;

FIG. 8 is a process diagram illustrating steps of a pump starting method according to a comparative example;

FIG. 9 is a process diagram illustrating steps of a pump starting method according to an embodiment;

FIG. 10A is a schematic explanatory diagram of a movement mode of a pump attachment plate according to embodiment 2;

FIG. 10B is a schematic explanatory diagram of the function of retaining parts;

FIG. 11 is a schematic explanatory diagram of a movement mode of a pump attachment plate according to embodiment 3;

FIG. 12 is a schematic explanatory diagram of a movement mode of the pump attachment plate according to embodiment 3;

FIG. 13 is a schematic explanatory diagram of a movement mode of the pump attachment plate according to embodiment 3;

FIG. 14 is a schematic explanatory diagram of a movement mode of the pump attachment plate according to embodiment 3;

FIG. 15 is a schematic explanatory diagram of a movement mode of the pump attachment plate according to embodiment 3;

FIG. 16 is a schematic explanatory diagram of a movement mode of the pump attachment plate according to embodiment 3;

FIG. 17 is an explanatory diagram of a pump attachment plate, a shaft member, and a shaft hole;

FIG. 18A is a perspective view illustrating a pump attachment plate and a shaft member from below;

FIG. 18B is a view of a shaft member along an axial direction thereof;

FIG. 19 is a sectional view taken along line XIX-XIX in FIG. 18A;

FIG. 20 is a perspective view of a base plate from below; and

FIG. 21 is an explanatory diagram of an effect of embodiment 3.

### DESCRIPTION OF EMBODIMENTS

Hereafter, embodiments are described in detail while referring to the accompanying drawings.

### Embodiment 1

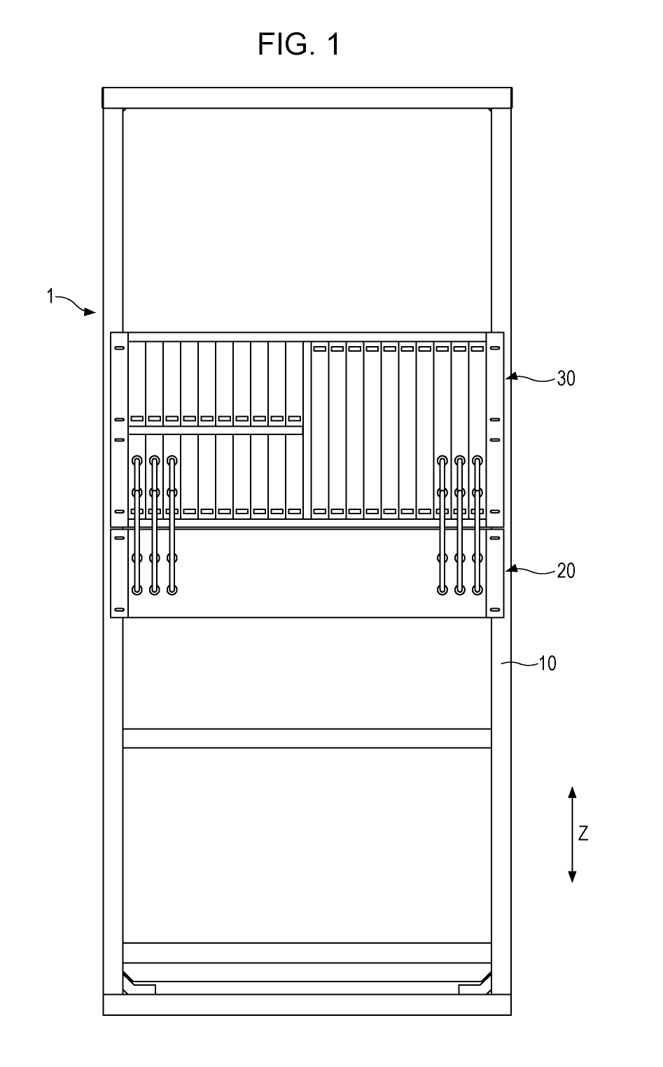

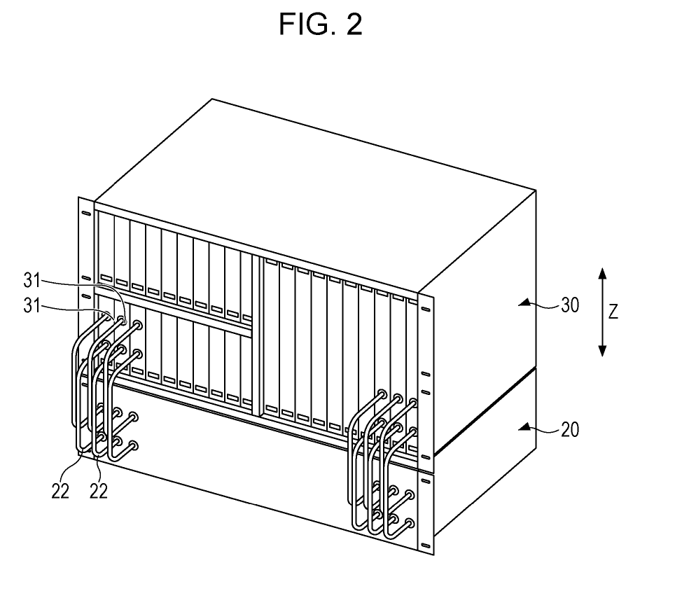

FIG. 1 is a front view illustrating an electronic apparatus 1 according to embodiment 1, and FIG. 2 is a perspective view illustrating a water cooling unit 20 and a bookshelf-type apparatus 30. In FIG. 1, a Z direction is defined. The Z direction corresponds to a height direction.

The electronic apparatus 1 is an apparatus in which a plurality of electronic units 31 is housed. The electronic units 31 are liquid-cooled apparatus that are cooled by a liquid refrigerant. The liquid refrigerant may be an antifreeze solution containing propylene glycol, for example. As an example, the electronic apparatus 1 forms a wireless communication base station. The electronic apparatus 1 may be disposed outdoors or indoors. In a modification, the electronic apparatus 1 may have the form of another electronic apparatus such as a server or a supercomputer.

The electronic apparatus 1 includes a rack (frame) 10, the water cooling unit 20, and the bookshelf-type apparatus 30.

The rack 10 forms a frame that supports the entirety of the electronic apparatus 1. The water cooling unit 20 and the bookshelf-type apparatus 30 are installed in the rack 10. In the example illustrated in FIG. 1, one set consisting of the water cooling unit 20 and the bookshelf-type apparatus 30 is installed in the rack 10, but alternatively multiple sets of the water cooling unit 20 and the bookshelf-type apparatus 30 may be installed in the rack 10. In addition, in embodiment 1, one water cooling unit 20 is provided for one bookshelf-type apparatus 30 as an example, but one water cooling unit 20 may instead be provided for a plurality of bookshelf-type apparatuses 30. Alternatively, a plurality of water cooling units 20 may be provided for one bookshelf-type apparatus 30.

The water cooling unit 20 is a device that cools the electronic units 31 installed inside the bookshelf-type apparatus 30 with a liquid refrigerant (secondary refrigerant). Hereafter, a secondary refrigerant may be simply referred to using the term “water”. For example, the term “water injection” means injecting a secondary refrigerant into a cooling system of the electronic apparatus 1.

The bookshelf-type apparatus 30 is an apparatus that houses the electronic units 31 in a “bookshelf”-like manner. Therefore, the electronic units 31 may have the form of cards that house electronic devices there inside, and may be referred to as plug in units (PIUs).

The electronic units 31 implement the various functions of a base station. The electronic units 31, which are targets of cooling, include devices (heat-emitting bodies) such as processing devices. In addition, the electronic units 31, which are targets of cooling, are equipped with flow paths inside thereof through which the secondary refrigerant flows, and consequently have a structure through which the heat of the devices may be released to the outside. The structure of the flow paths inside the electronic units 31 is arbitrary. For example, inside each electronic unit 31, the secondary refrigerant flow path may be formed so as to contact a heat-radiating part (liquid-cooling cold plate) that is thermally connected to a device, or may be formed so as to extend through the inside of the heat-radiating part.

The plurality of electronic units 31 may all have the same configuration that implements the same functions, or may include units that generally implement different functions. Therefore, the plurality of electronic units 31 may have different sizes.

Each of the electronic units 31, which are targets of cooling, communicate with the water cooling unit 20 via pipelines 22, as illustrated in FIG. 2. The pipelines 22 include pipelines that are for feeding the secondary refrigerant and pipelines that are for returning the secondary refrigerant.

In the electronic apparatus 1, which forms a base station, there is typically a large number of electronic units 31 housed in a single bookshelf-type apparatus 30. The number of electronic units 31 is around 30-50 for a bookshelf-type apparatus 30 that is around 8U (1U=1.75 inches=44.45 mm). In contrast, the number is around 30 per rack for a server or the like.

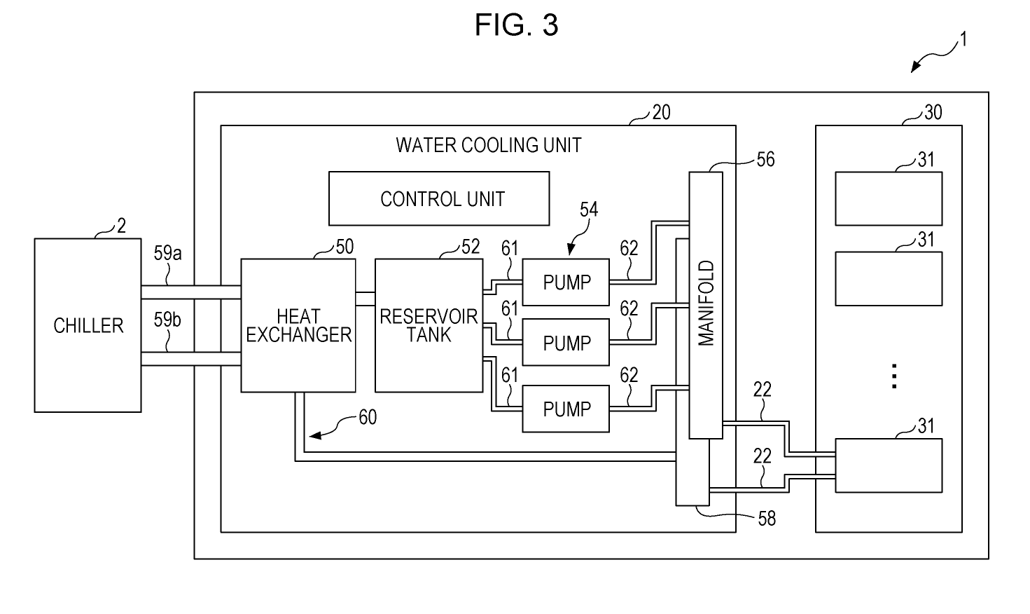

Next, the cooling system of the electronic apparatus 1 will be described while referring to FIG. 3.

FIG. 3 is an explanatory diagram giving an overview of the cooling system of the electronic apparatus 1. In FIG. 3, the flow path is represented by double lines. In addition, a chiller 2, which is installed outside the electronic apparatus 1, is schematically illustrated in FIG. 3. Furthermore, the pipelines 22 related to one electronic unit 31 are illustrated in FIG. 3 as a representative example.

The cooling system of the electronic apparatus 1 includes a heat exchanger 50, a reservoir tank 52, pumps 54, a feeding-side manifold 56, a return-side manifold 58, and a water-cooling-unit flow path 60.

The heat exchanger 50, the reservoir tank 52, the pumps 54, the feeding-side manifold 56, the return-side manifold 58, and the water-cooling-unit flow path 60 are provided inside the water cooling unit 20. However, some of these elements may alternatively be provided outside the water cooling unit 20.

The heat exchanger 50 is a device performs heat exchange between a primary refrigerant and a secondary refrigerant. The primary refrigerant is fed from the chiller 2 outside the electronic apparatus 1 via a flow path 59a, and returns to the chiller 2 via a flow path 59b. Heat exchange is realized between a liquid primary refrigerant and a liquid secondary refrigerant in the heat exchanger 50, but heat exchange may additionally be realized between the outside air and the secondary refrigerant in the heat exchanger 50.

The reservoir tank 52 is a tank that stores the secondary refrigerant.

The pumps 54 are provided between the reservoir tank 52 and the feeding-side manifold 56. Specifically, the pumps 54 are connected to the reservoir tank 52 via hoses 61 (example of first flow path member), and are connected to the feeding-side manifold 56 via hoses 62 (example of second flow path member). The hoses 61 and 62 are flexible. The two ends of each hose 61 may be respectively connected to the reservoir tank 52 and the corresponding pump 54 using non-spill coupling joints such as couplers. Similarly, the two ends of each hose 62 may be respectively connected to the corresponding pump 54 and the feeding-side manifold 56 using non-spill coupling joints such as couplers. Thus, the hoses may be easily detached and attached when performing maintenance and so forth. The pumps 54 suck in and discharge the secondary refrigerant inside the reservoir tank 52 when operating. The pumps 54 are variable discharge flow rate pumps, for example. The pumps 54 are electric pumps, for example. A plurality of the pumps 54 may be provided as illustrated in FIG. 3, or just one pump 54 may be provided.

The feeding-side manifold 56 is a member that is also called a “header”, and stores branching-feeding-use secondary refrigerant discharged from the pumps 54. The pipelines 22 that are for feeding the secondary refrigerant to the electronic units 31 are connected to the feeding-side manifold 56.

The return-side manifold 58 is a member that is also called a “header”, and accumulates and stores secondary refrigerant that is to be returned to the heat exchanger 50. The pipelines 22 that are on the return side relative to the electronic units 31 are connected to the return-side manifold 58.

The water-cooling-unit flow path 60 includes various connection hoses including the hoses 61 and 62. The water-cooling-unit flow path 60 is a flow path that connects the heat exchanger 50, the reservoir tank 52, the pumps 54, the feeding-side manifold 56, and the return-side manifold 58 to each other. The water-cooling-unit flow path 60 forms a secondary refrigerant circulation path together with the pipelines 22 and the flow paths inside the electronic units 31 (not illustrated).

Specifically, the secondary refrigerant from the heat exchanger 50 is stored in the reservoir tank 52, and is fed from the reservoir tank 52 to the feeding-side manifold 56 by the pumps 54. The secondary refrigerant is fed from the feeding-side manifold 56 to the flow paths inside the electronic units 31 (not illustrated) via the feeding-side pipelines 22. The secondary refrigerant from the flow paths inside the electronic units 31 is returned to the return-side manifold 58 via the return-side pipelines 22. The secondary refrigerant from the return-side manifold 58 is returned once more to the heat exchanger 50 via the water-cooling-unit flow path 60 (return side). In this way, the secondary refrigerant circulates through the cooling system while receiving heat in the electronic units 31 and radiating heat in the heat exchanger 50.

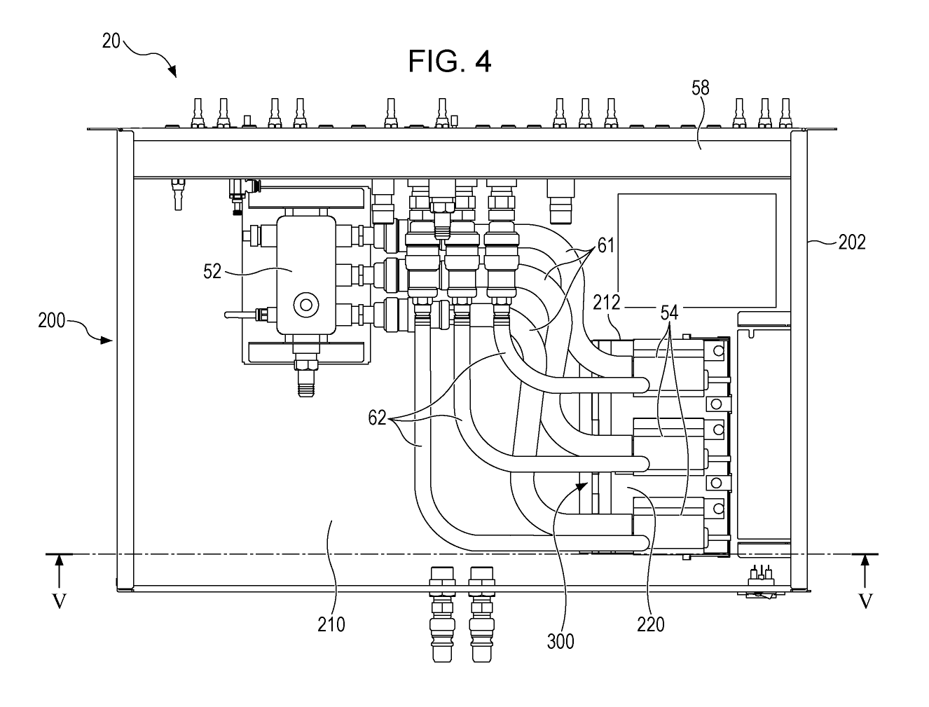

Next, referring to FIGS. 4 to 7, the casing structure and a pump-lowering parts of the water cooling unit 20 are described.

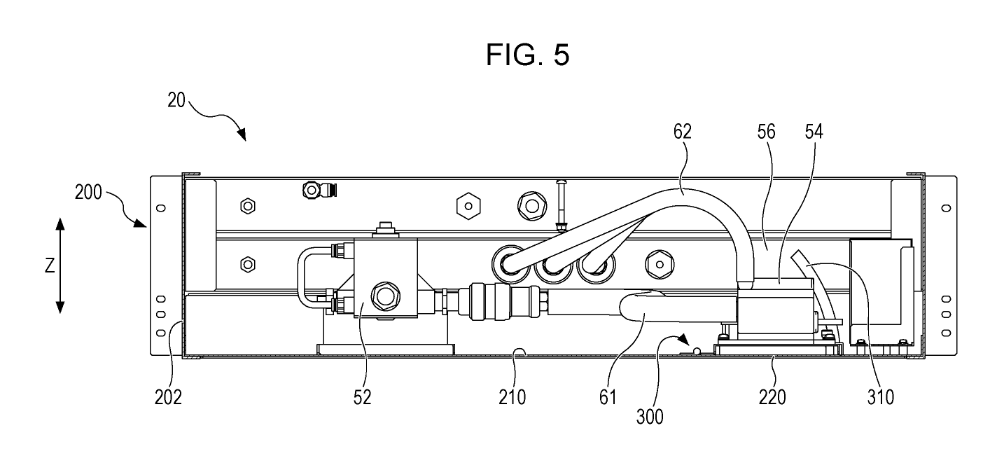

FIG. 4 is a plan view of the water cooling unit 20, and FIG. 5 is a diagram illustrating a cross section taken along line V-V in FIG. 4 and illustrates members on the side of the line V-V indicated by the arrows. In addition, in FIGS. 4 and 5, illustration of some constituent components such as the heat exchanger 50 is omitted.

The water cooling unit 20 includes a box-shaped casing 200 that is open at the top.

The casing 200 includes a side plate 202, a base plate 210 (example of first support member), and a pump attachment plate 220 (example of second support member). The side plate 202 stands upright so as to surround the entire periphery of the base plate 210.

The base plate 210 forms a bottom part of the casing 200 together with the pump attachment plate 220. Various constituent components other than the pumps 54 are attached to the base plate 210. For example, the reservoir tank 52 is fixed to the base plate 210. The base plate 210 has an opening 212, and the pump attachment plate 220 is provided so as to close the opening 212.

The pump attachment plate 220 is a plate that extends at substantially the same height as the base plate 210. The pumps 54 are attached to the pump attachment plate 220. In other words, the pumps 54 are fixed to and supported by the pump attachment plate 220. The pump attachment plate 220 is provided so as to be able to move with respect to the base plate 210. Specifically, the pump attachment plate 220 is rotatably supported by the base plate 210 using a hinge 300.

Inside the water cooling unit 20, as illustrated in FIG. 5, the reservoir tank 52 is only disposed at a position that is slightly higher than the pumps 54 due to height restrictions and so forth.

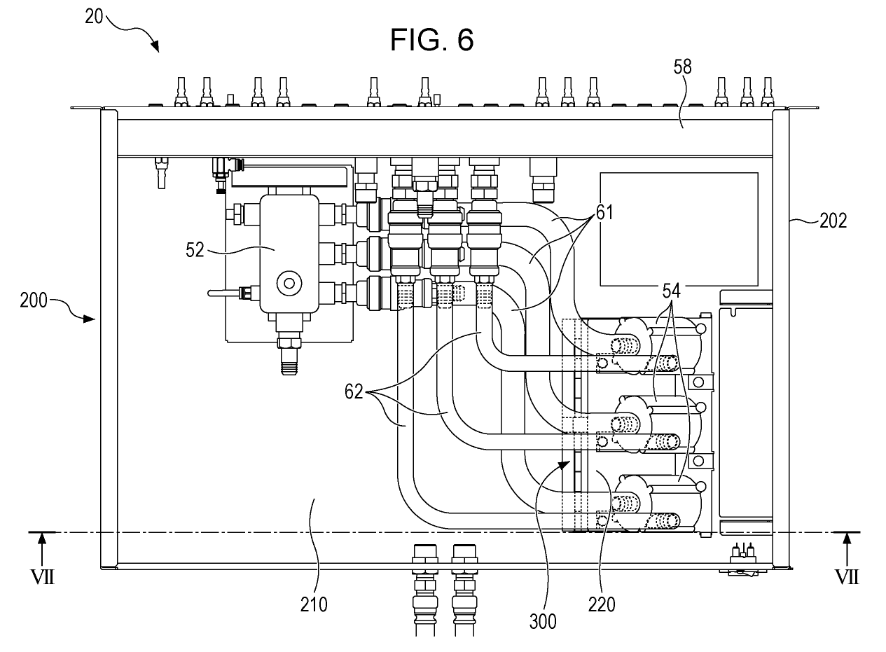

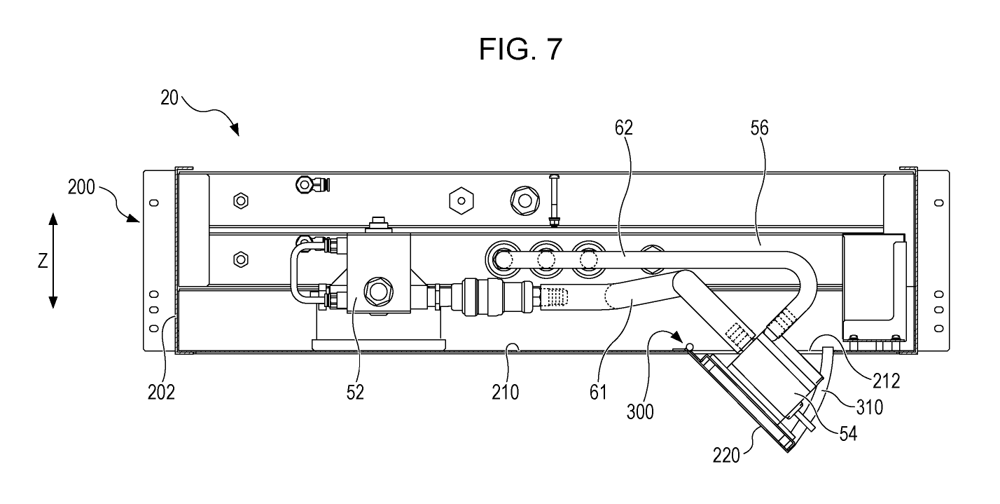

FIGS. 6 and 7 are explanatory diagrams of a movement mode of the pump attachment plate 220, and are diagrams illustrating a state in which the pump attachment plate 220 has been moved to a lower position. FIG. 6 is a plan view corresponding to FIG. 4, and FIG. 7 is a diagram illustrating a cross section taken along line VII-VII in FIG. 6, and illustrates members on the side of the line VII-VII indicated by the arrows.

The hinge 300 forms a horizontal-direction rotational axis. Therefore, as illustrated in FIGS. 6 and 7, the pump attachment plate 220 is able to rotate around the horizontal-direction rotational axis. Thus, the hinge 300 forms an example of a pump-lowering parts. Hereafter, the position illustrated in FIGS. 4 and 5 is referred to as a normal position of the pump attachment plate 220 (example of first position), and the position illustrated in FIGS. 6 and 7 is referred to as a lowered position of the pump attachment plate 220 (example of second position). In addition, the lowered position (rotation angle) of the pump attachment plate 220 may be regulated by a stopper member 310. Furthermore, holding of the pump attachment plate 220 at the normal position (holding the pump attachment plate 220 against gravity) may be implemented using a locking structure using a spring or the like or with a simple fastener (not illustrated).

When the pump attachment plate 220 is located at the lowered position illustrated in FIGS. 6 and 7, the pumps 54 on the pump attachment plate 220 also reach a position that is lower than that in the case where the pump attachment plate 220 is located at the normal position illustrated in FIGS. 4 and 5. Thus, as described later, starting of the pumps 54, which accompanies water injection, is easy. In addition, the hoses 61 and 62 are routed so as to have excess length that is able to accommodate the movement of the pumps 54 that accompanies the movement of the pump attachment plate 220.

When assembling the water cooling unit 20, the secondary refrigerant from the reservoir tank 52 is made to circulate through the circulation path using the pumps 54 in order to fill the circulation path with the secondary refrigerant. The pumps 54 are started in order to fill the circulation path with the secondary refrigerant, but it is desirable to perform priming from the pump intake ports in order to avoid pump seizure caused by idling when the pumps 54 are started. It is desirable to position the reservoir tank 52 at a higher position than the pumps 54 in order to perform priming.

However, when the pump attachment plate 220 is at the normal position, as described above, the discharge ports of the reservoir tank 52 and the intake ports of the pumps 54 are in a substantially horizontal relationship with respect to each other. This is because it not is possible to secure a sufficient height in the vertical-direction positional relationship between the reservoir tank 52 and the pumps 54 in the water cooling unit 20 installed in the rack 10, as described above.

Regarding this point, according to this embodiment, the pump attachment plate 220 may be moved to the lowered position illustrated in FIGS. 6 and 7, and therefore it is possible to relatively move the reservoir tank 52 to a high position with respect to the pumps 54 by moving the pump attachment plate 220 to the lowered position when performing priming. Thus, starting of the pumps 54, which accompanies water injection, may be realized through simple work of moving the pump attachment plate 220 to the lowered position using the pump-lowering parts. As a result, work in which the reservoir tank 52 is moved upward by detaching the reservoir tank 52 from the water cooling unit 20 may be avoided, and the inconvenience caused by such work may be removed. Furthermore, as an example of an inconvenience that may be caused when the reservoir tank 52 is moved upward by detaching the reservoir tank 52 from the water cooling unit 20, in addition to the work itself being complex, there is a possibility of the secondary refrigerant leaking due the abnormal posture of the reservoir tank 52 when the reservoir tank 52 is moved to a high position. In addition, similarly, there is a possibility of secondary refrigerant leaks being caused by, for example, the hoses becoming detached from the reservoir tank 52 due to the abnormal posture of the reservoir tank 52. According to this embodiment, it is possible to remove the possibility of such leakage of the secondary refrigerant.

In addition, according to this embodiment, in the state where the water cooling unit 20 is installed in the rack 10, when there is sufficient space below the water cooling unit 20, it is possible to start the pumps 54 accompanying water injection without removing the water cooling unit 20 from the rack 10.

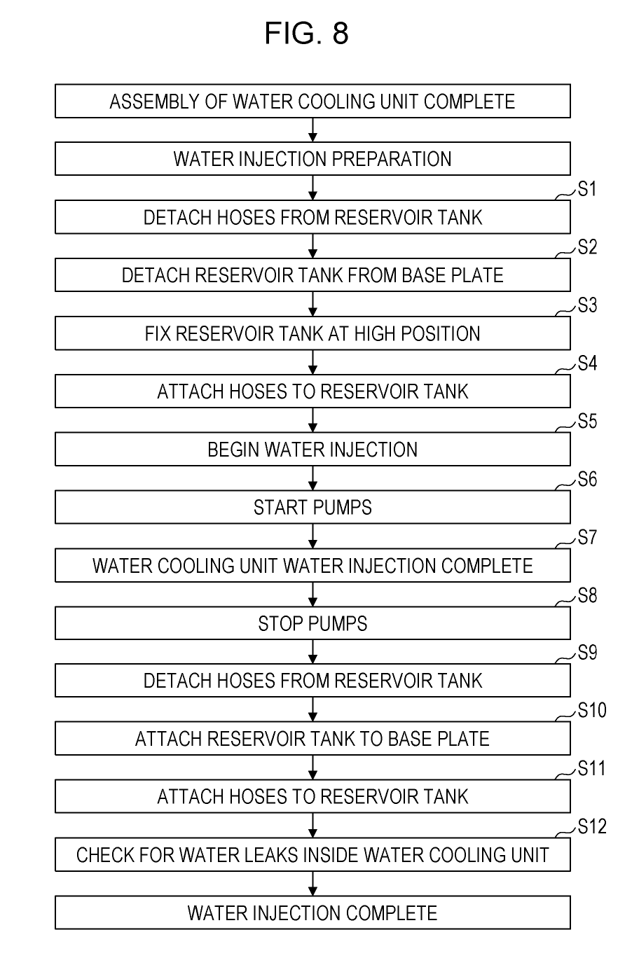

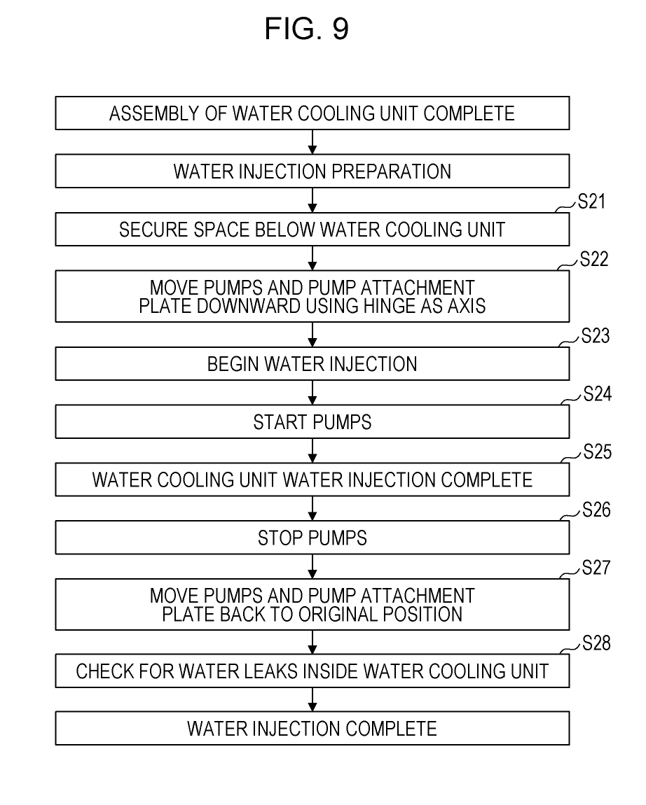

Next, a pump starting method is additionally described by being compared with a comparative example while referring to FIGS. 8 and 9.

FIG. 8 is a process diagram illustrating the steps of a pump starting method according to a comparative example, and FIG. 9 is a process diagram illustrating steps of a pump starting method according to this embodiment.

As illustrated in FIG. 8, for example, once assembly of the water cooling unit 20 is complete, water injection preparation is performed, and then the pump starting method according to the comparative example is executed. In the pump starting method according to the comparative example, first, work of detaching the reservoir tank from the water cooling unit (S2) and work of moving the reservoir tank upward (S3) are performed together. In addition, work of detaching the hoses from the reservoir tank (S1) and reattaching the hoses (S4) to the reservoir tank accompanies the work performed at this time. Furthermore, water injection is started (S5), the pumps are started (S6), and once water filling is complete, the water injection process is complete, and the pumps are stopped (S8). After that, work of returning the reservoir tank to its original location (S10) is performed, and at this time, work of once again detaching the hoses from the reservoir tank (S9) and reattaching the hoses to the reservoir tank (S11) is performed. After that, once checking for water leaks is complete (S12), the water injection process is complete.

As illustrated in FIG. 9, similarly, for example, once assembly of the water cooling unit 20 is complete, water injection preparation is performed, and then the pump starting method according to this embodiment is executed. In the pump starting method according to this embodiment, sufficient space is secured below the water cooling unit 20 (S21), and then the pump attachment plate 220 and the pumps 54 are moved to the lowered position (S22). At this time, work of detaching the hoses 61 and 62 is not performed. Next, water injection is started (S23), the pumps are started (S24), and once water filling is complete (S25), the water injection process is complete, and the pumps are stopped (S26). After that, the pump attachment plate 220 and the pumps 54 are returned to the normal position (S27). Work of detaching the hoses 61 and 62 is not performed at this time either. After that, once checking for water leaks is complete (S28), the water injection process is complete.

As is clear from the above comparison with the comparative example, this embodiment is able to greatly simplify the steps of the pump starting method. In addition, as described above, since detachment of the hoses 61 and 62 and so on is not performed, the possibility of water leakage may also be decreased.

In addition, although the pump starting method is performed once the assembly of the water cooling unit 20 is complete in the example illustrated in FIG. 9, a similar method may also be used to start the pumps 54 after replacing or performing maintenance on the pumps 54, for example. For example, when one out of three pumps 54 has been replaced, the replaced pump 54 may be started using the starting method illustrated in FIG. 9 while the other two pumps 54 are running.

### Embodiment 2

The structure of the casing in embodiment 2 is different from that in embodiment 1 described above. More specifically, the movement mode of the pump attachment plate is in embodiment 2 is different from that in embodiment 1 described above. The following description mainly focuses on the parts of embodiment 2 that are different from embodiment 1.

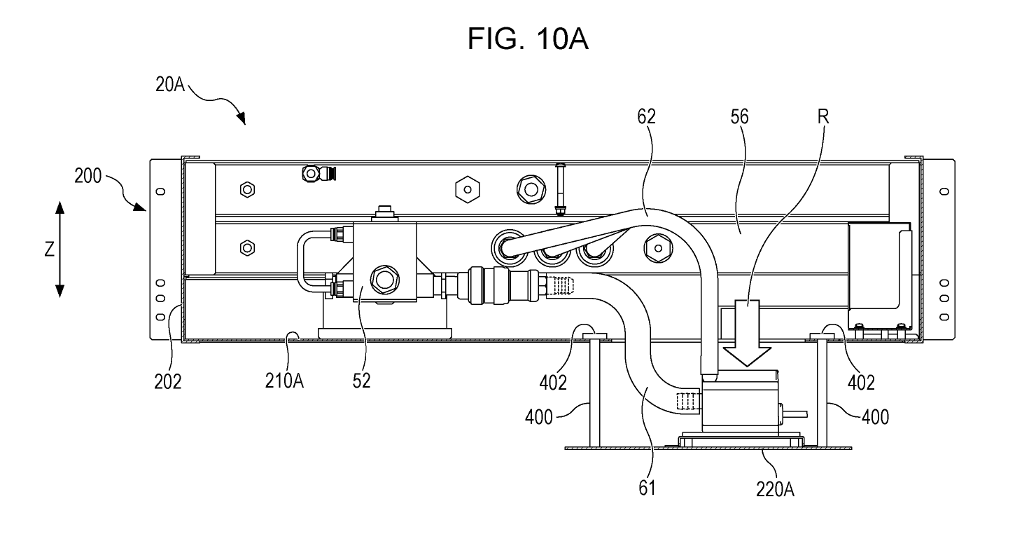

FIG. 10A is a schematic explanatory diagram of a movement mode of a pump attachment plate 220A according to embodiment 2. In FIG. 10A, constituent elements that may be the same as in embodiment 1 described above are denoted by the same reference symbols and description thereof is omitted.

A pump-lowering parts according to embodiment 2 differs from that according to embodiment 1 in that guide rods 400 are used instead of the hinge 300.

The pump attachment plate 220A is connected so as to be able to move up and down with respect to a base plate 210A via the guide rods 400, which extend in a vertical direction. Specifically, the guide rods 400 are provided so as to stand upright at the four corners of the pump attachment plate 220A when viewed from above, for example. The lower ends of the guide rods 400 are fixed to the pump attachment plate 220A, and retaining parts 402 are provided at the upper ends of the guide rods 400.

The pump attachment plate 220A may be moved to the lowered position (example of second position) illustrated in FIG. 10A. The normal position of the pump attachment plate 220A is within a horizontal plane that is substantially the same as that of the base plate 210A. Holding of the pump attachment plate 220A at the normal position (holding the pump attachment plate 220A against gravity) may be implemented using a locking structure using a spring or the like or with a simple fastener (not illustrated).

FIG. 10B is a schematic diagram for explaining the function of the retaining parts 402, and depicts a plan view of the pump attachment plate 220A and part of the base plate 210A.

The base plate 210A has an opening 212A that is slightly smaller than the pump attachment plate 220A. In addition, the base plate 210A includes holes 214A through which the guide rods 400 pass. The retaining parts 402 realize a retaining function by contacting the regions surrounding the holes 214A in the base plate 210A in the downward direction. In other words, the retaining parts 402 are larger than the holes 214A and contact the regions surrounding the holes 214A in the base plate 210A, and consequently, further downward displacement of the retaining parts 402 is restricted.

The same effect as exhibited by embodiment 1 described above is also exhibited by the pump-lowering parts according to embodiment 2. In other words, when injecting the secondary refrigerant, the pump attachment plate 220A is moved to the lowered position, and the pumps 54 are moved down together with the movement of the pump attachment plate 220A. Thus, the pumps 54 may be positioned below the reservoir tank 52, and water injection may be performed without attaching and detaching the reservoir tank 52 and the hoses 61 and 62.

### Embodiment 3

The structure of the casing in embodiment 3 is different from that in embodiment 1 described above. More specifically, the movement mode of the pump attachment plate in embodiment 3 is different from that in embodiment 1 described above. The following description mainly focuses on the parts of embodiment 3 that are different from embodiment 1.

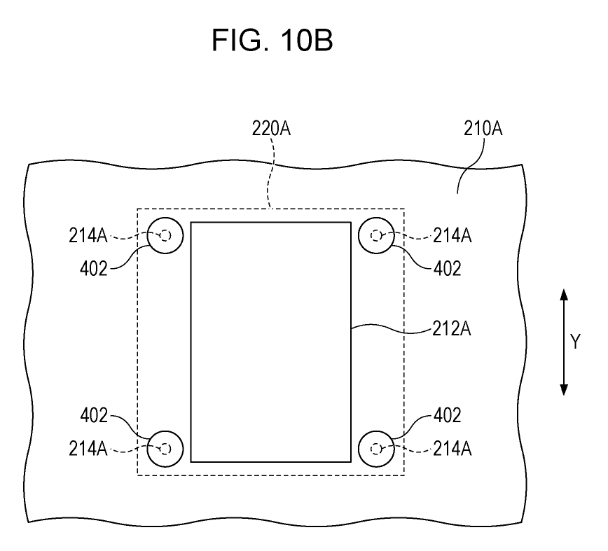

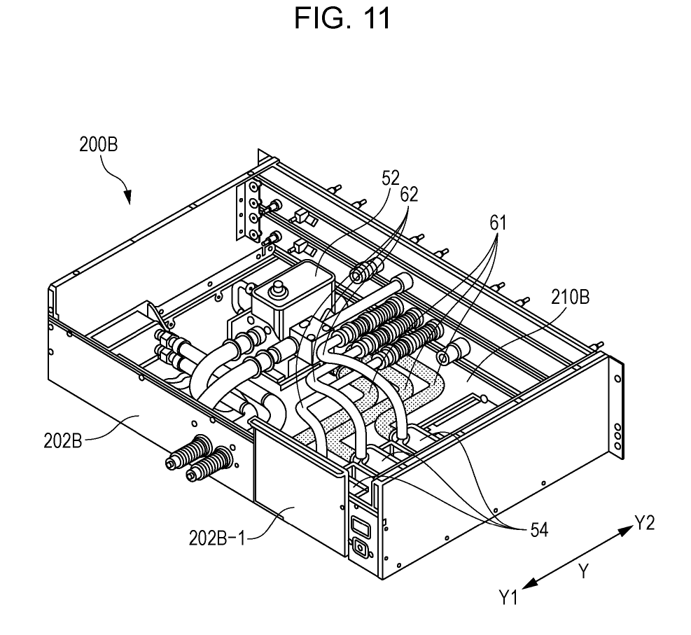

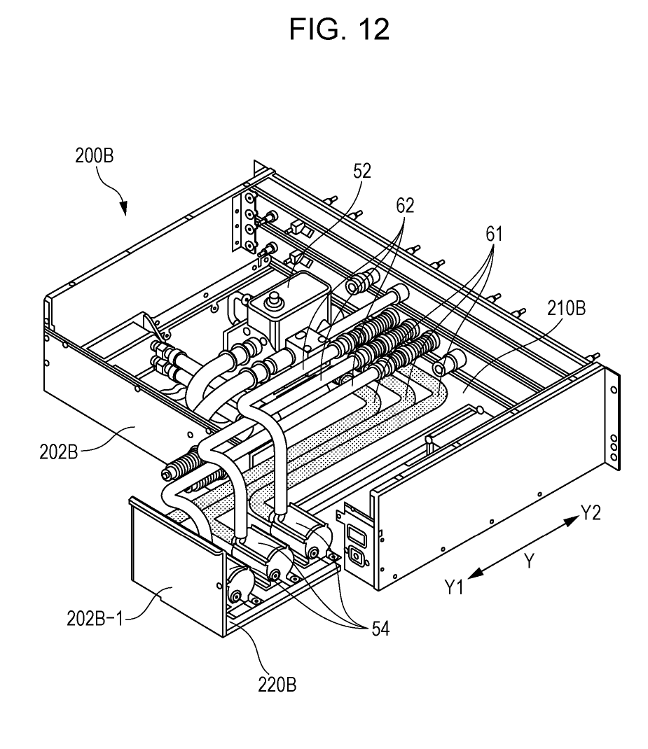

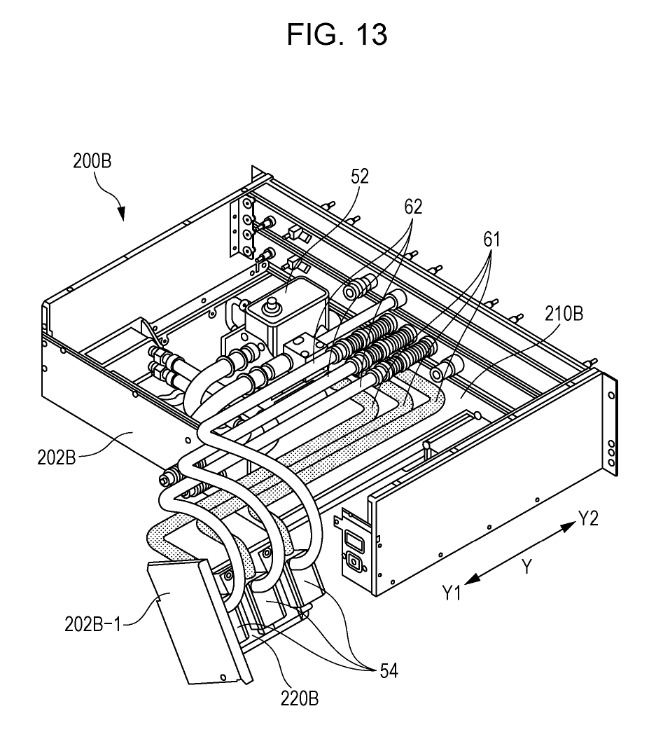

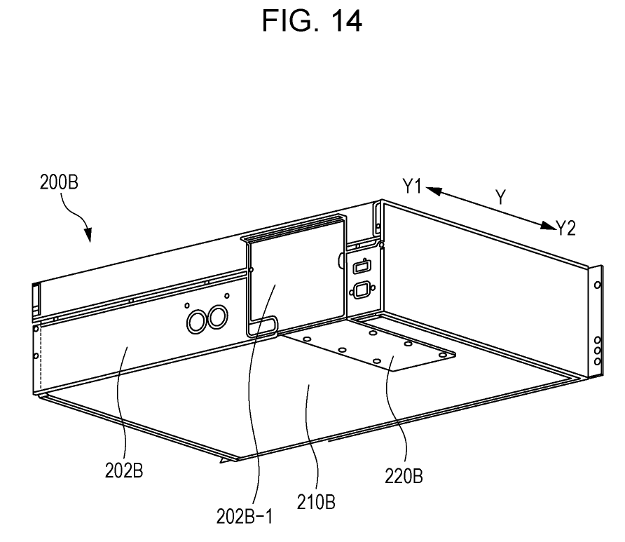

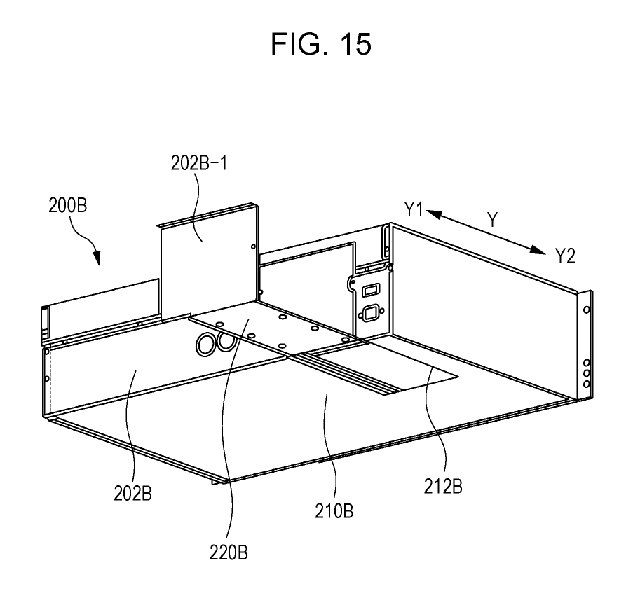

FIGS. 11 to 16 are schematic explanatory diagrams of a movement mode of a pump attachment plate 220B according to embodiment 3. FIGS. 11 to 13 are perspective views of a casing 200B from above, and FIGS. 14 to 16 are perspective views illustrating the relationship between the pump attachment plate 220B and a base plate 210B from below. FIGS. 11 and 14 illustrate a state in which the pump attachment plate 220B is located at the normal position, FIGS. 12 and 15 illustrate a state in which the pump attachment plate 220B is located at a slid-out position, and FIGS. 13 and 16 illustrate a state in which the pump attachment plate 220B is located at the lowered position. In FIGS. 11 to 16, constituent elements that may be the same as in embodiment 1 described above are denoted by the same reference symbols and description thereof is omitted. A Y axis that extends in a sliding direction is defined in FIG. 12. The Y axis is an axis that lies within a horizontal plane. In addition, although the way in which the hoses 62 are connected in FIGS. 11 to 13 is different from that illustrated in the previously discussed FIG. 4 and so on, this difference is not a fundamental feature. In FIGS. 14 to 16, illustration of the pumps 54 and so on is omitted.

A pump-lowering parts according to embodiment 3 differs from that according to embodiment 1 in that a combination of a sliding parts and a rotation parts is used instead of the hinge 300.

The pump attachment plate 220B is slidably and rotatably connected to the base plate 210B via the combination of the horizontal-direction sliding parts and the rotation parts, which rotates around a horizontal-direction rotational axis. Specifically, the pump attachment plate 220B may be moved from the normal position illustrated in FIGS. 11 and 14 to the slid-out position on the rear side (Y1 side in Y direction) via the sliding parts as illustrated in FIGS. 12 and 15. Once the pump attachment plate 220B has been moved to the slid-out position, the rotation parts functions and the pump attachment plate 220B is able to move to the lowered position (example of second position) via the Y-axis rotation parts, as illustrated in FIGS. 13 and 16. The normal position of the pump attachment plate 220B is within a horizontal plane that is substantially the same as that of the base plate 210B.

This combination of the sliding parts and the rotation parts includes a shaft member 500 and a shaft hole 600.

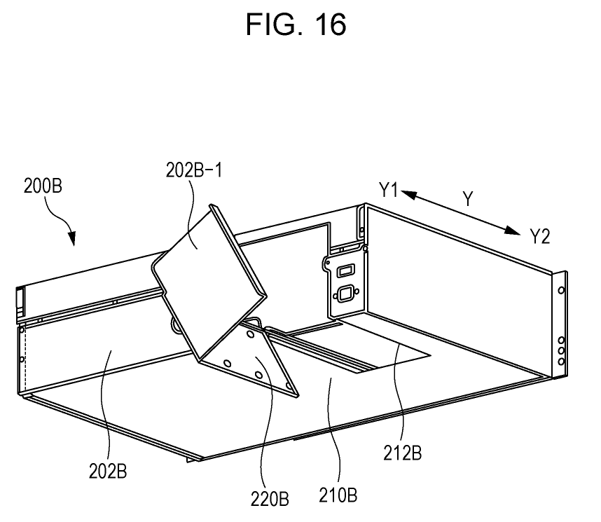

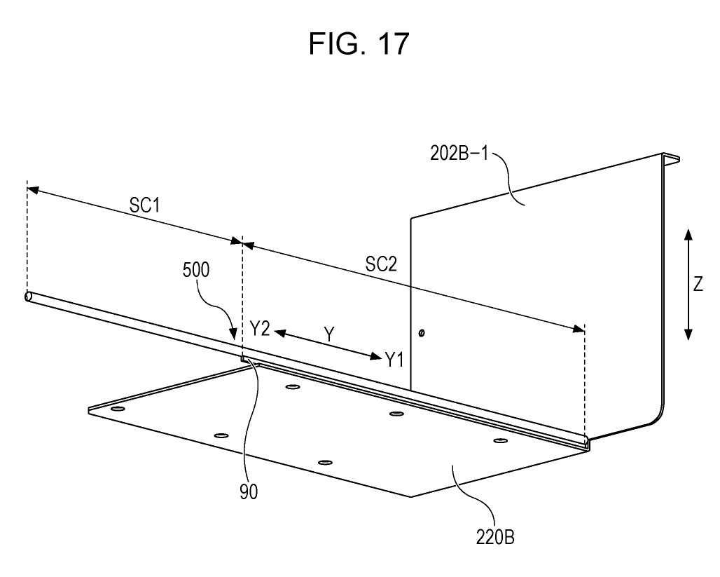

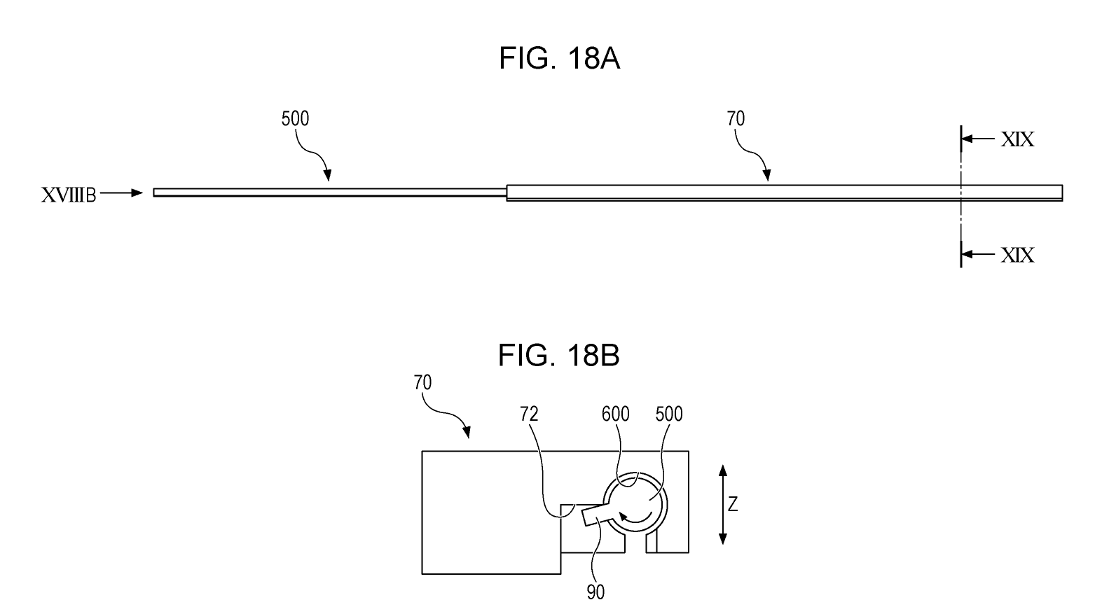

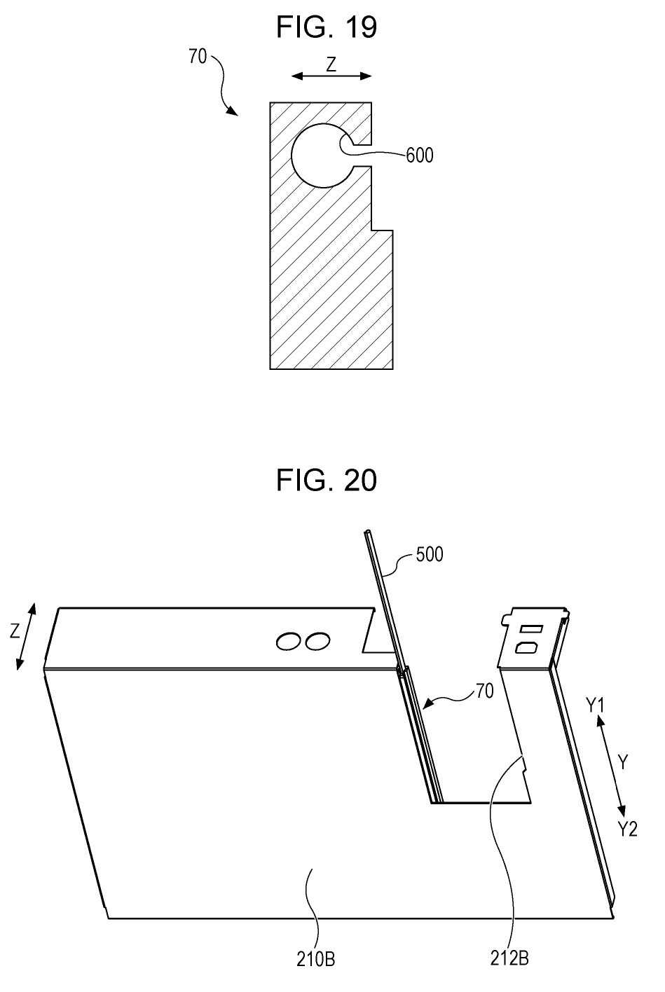

FIGS. 17, 18A, and 18B are diagrams for describing the pump attachment plate 220B, the shaft member 500, and the shaft hole 600. FIG. 17 is a perspective view that illustrates the pump attachment plate 220B and the shaft member 500 from below. FIGS. 18A and 18B are two diagrams that illustrate the relationship between the shaft member 500 and the shaft hole 600. FIG. 18A is a side view of the shaft member 500, and FIG. 18B is an axial direction view of the shaft member 500, and is taken along the direction of arrow XVIIIB in FIG. 18A (view along arrow XVIIIB). FIG. 19 is a sectional view taken along line XIX-XIX in FIG. 18A. FIG. 20 is a perspective view of the base plate 210B from below. FIG. 20 also illustrates the shaft member 500 at a position corresponding to the slid-out position.

The structure of the pump attachment plate 220B differs from that of the pump attachment plate 220 according to embodiment 1 described above in that a side plate part 202B-1 and the shaft member 500 are fixed thereto.

The side plate part 202B-1 forms part of a side plate 202B (part of side plate 202B on Y1 side in Y direction). Therefore, the pump attachment plate 220B extends up to the side plate part 202B-1 in the Y direction. The side plate part 202B-1 is able to function as a handle part when pulling the pump attachment plate 220B out to the slid-out position.

The shaft member 500 extends in the Y direction. As illustrated in FIG. 17, the shaft member 500 has a first section SC1 that has a circular cross-sectional shape and a second section SC2 that has a cross-sectional shape that is circular with a protrusion 90. In the second section SC2, the protrusion 90 protrudes downwardly and forms a projection that extends in the Y direction.

In addition to an opening 212B, which corresponds to the area in which the pump attachment plate 220B is formed, being formed in a different area, the base plate 210B also differs from the base plate 210 according to embodiment 1 described above in that the base plate 210B is equipped with the shaft hole 600. The shaft hole 600 may be integrally formed with the base plate 210B, but in this case, as illustrated in FIG. 20, the shaft hole 600 is formed in a block member 70 and the block member 70 is fixed to a lower surface of the base plate 210B.

The shaft hole 600 extends in the Y direction. The shaft member 500 is inserted into the inside of the shaft hole 600. The shaft hole 600 has a cross-sectional shape that allows the first section SC1 part of the shaft member 500 to rotate and does not allow the second section SC2 part of the shaft member 500 to rotate. Specifically, as illustrated in FIG. 19, the cross-sectional shape of the shaft hole 600 is a key hole shape corresponding to the second section SC2 part of the shaft member 500. In addition, in the example illustrated in FIG. 19, the shaft hole 600 is open in the downward direction, but may instead be closed in the downward direction.

When the pump attachment plate 220B is located between the normal position and the slid-out position, the second section SC2 part of the shaft member 500 is located inside the shaft hole 600. Thus, when the pump attachment plate 220B is located in the region between the normal position and the slid-out position, rotation of the shaft member 500 is restricted. In other words, when the pump attachment plate 220B is located in the region between the normal position and the slid-out position, the pump attachment plate 220B is unable to rotate with respect to the base plate 210B.

When the pump attachment plate 220B is located at the slid-out position, the second section SC2 part of the shaft member 500 protrudes from the shaft hole 600 and only the first section SC1 part of the shaft member 500 is located inside the shaft hole 600. In other words, once the pump attachment plate 220B reaches the slid-out position, the restriction against the rotation of the shaft member 500 is removed. As a result, at the slid-out position, the pump attachment plate 220B is rotated by gravity to the lowered position. In addition, the lowered position (rotation angle) of the pump attachment plate 220B may be regulated by a stopper 72 of the block member 70, as illustrated in FIG. 18B.

The same effect as exhibited by embodiment 1 described above is also exhibited by the pump-lowering parts according to embodiment 3. In other words, when injecting the secondary refrigerant, the pump attachment plate 220B is moved to the lowered position, and the pumps 54 are moved down together with the movement of the pump attachment plate 220B. Thus, the pumps 54 may be positioned below the reservoir tank 52, and water injection may be performed without attaching and detaching the reservoir tank 52 and the hoses 61 and 62.

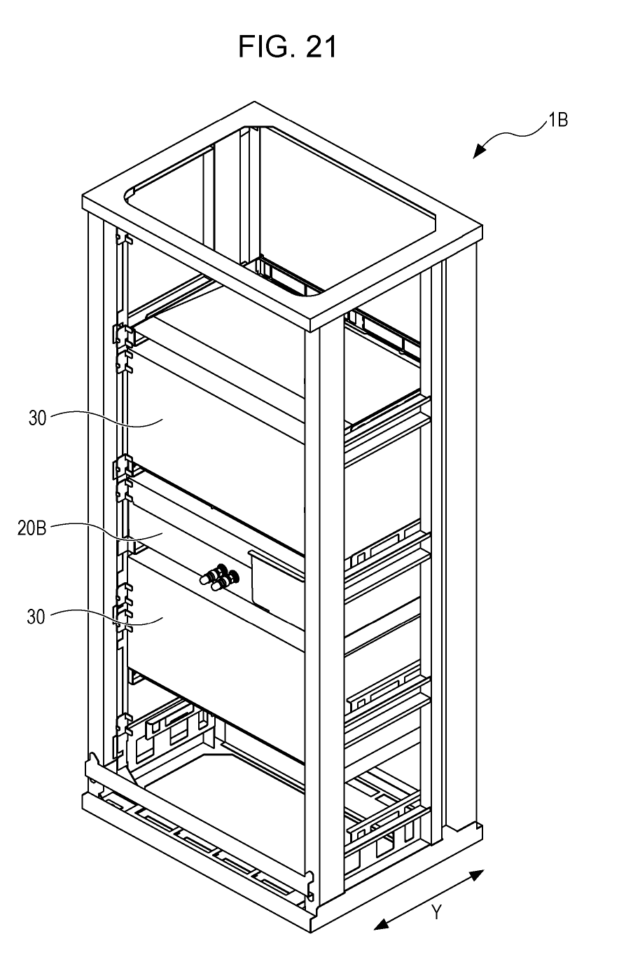

In addition, according to embodiment 3, as described above, the pump attachment plate 220B and the accompanying pumps 54 may be pulled out to the slid-out position and then moved to the lowered position. Therefore, according to embodiment 3, as schematically illustrated in FIG. 21, for example, injection of the secondary refrigerant may still be performed even in the case where a bookshelf-type apparatus 30 is provided below a water cooling unit 20B and there is insufficient space below the water cooling unit 20B. In other words, according to embodiment 3, the pump attachment plate 220B may be pulled out to the slid-out position and then moved to the lowered position even in the case where a bookshelf-type apparatus 30 is provided below the water cooling unit 20B, as illustrated in FIG. 21. In addition, an electronic apparatus 1B that includes the water cooling unit 20B is illustrated in FIG. 21.

Furthermore, in embodiment 3 described above, although the shaft member 500 is attached to the pump attachment plate 220B, and the block member 70 is attached to the base plate 210B, a configuration in which this relationship is reversed may be alternatively adopted. In other words, the base plate may be provided with a shaft member corresponding to the shaft member 500, and the pump attachment plate may be provided with a shaft hole corresponding to the shaft hole 600.

Embodiments have been described in detail above, but the present disclosure is not limited to specific embodiments, and may be modified and changed in various ways within the scope described in the claims. In addition, all or a plurality of the constituent elements of the above-described embodiments may be combined with each other.

For example, although a plurality of the pumps 54 are provided and the same pump attachment plate 220 is commonly provided for the plurality of pumps 54 in embodiment 1 described above (also the case in embodiments 2 and 3), the present disclosure is not limited to this configuration. For example, pump attachment plates 220 may be individually provided for the plurality of pumps 54, and the individual pump attachment plates 220 may be able to move independently of each other. In this case, when any one of the plurality of pumps 54 is to be replaced or the like, the water injection work may be performed without changing the positions of the other pumps 54.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An electronic apparatus comprising:
a reservoir tank that store a liquid refrigerant;
a pump;
a pump-lowering parts that allows the pump to be lowered to a position that is lower than the reservoir tank; and
a first flow path member that is coupled between the reservoir tank and the pump, and is flexible.

2. The electronic apparatus according to claim 1, further comprising:
a rack; and
a casing that is fixed to the rack, and houses the reservoir tank and the pump;
wherein the casing includes
a first support member to which the reservoir tank is fixed, and
a second support member to which the pump is fixed,
the pump-lowering parts is coupled to the first support member such that the second support member is able to move between a first position and a second position that is lower than the first position, and
the pump is lowered to a position that is lower than the reservoir tank together with movement of the second support member from the first position to the second position.

3. The electronic apparatus according to claim 2,
wherein the pump-lowering parts includes a hinge that forms a horizontal-direction rotational axis, and
the second support member is rotatably coupled to the first support member via the hinge.

4. The electronic apparatus according to claim 2,
wherein the pump-lowering parts includes a guide rod that extends in a vertical direction, and
the second support member is coupled to the first support member via the guide rod so as to be able to move vertically.

5. The electronic apparatus according to claim 2,
wherein the pump-lowering parts includes a combination of a horizontal-direction sliding parts and a rotation parts for rotation around a horizontal-direction rotational axis,
the second support member is slidably and rotatably coupled to the first support member via the combination of the sliding parts and the rotation parts,
the second support member is able to slide at the first position to a slid-out position via the sliding parts, and
the second support member is able to rotate at the slid-out position to the second position via the rotation parts.

6. The electronic apparatus according to claim 5,
wherein the combination of the sliding parts and the rotation parts includes
a shaft member that is disposed on one out of the first support member and the second support member, extends in a horizontal direction, and has a first section having a circular cross section and a second section having a cross section that is circular with a protrusion, and
a shaft hole that is disposed in another one out of the first support member and the second support member, that extends in the horizontal direction, that has the shaft member inserted thereinto, and that has a cross sectional shape that allows a part of the shaft member that is in the first section to rotate and that does not allow a part of the shaft member that is in the second section to rotate, and
the part of the shaft member that is in the second section is located inside the shaft hole when the second support member is located between the first position and the slid-out position, and the part of the shaft member that is in the second section protrudes from the shaft hole and only the part of the shaft member that is in the first section is located inside the shaft hole when the second support member is located at the slid-out position.

7. The electronic apparatus according to claim 2,
wherein the first flow path member has excess length that is able to accommodate the movement of the second support member between the first position and the second position.

8. The electronic apparatus according to claim 2, further comprising:
a manifold; and
a second flow path member that is coupled between the manifold and the pump, and is flexible;
wherein the second flow path member has excess length that is able to accommodate the movement of the second support member between the first position and the second position.

9. The electronic apparatus according to claim 2,
wherein the first support member is formed of a base plate of the casing, and
the second support member is a plate that is disposed in an opening of the base plate, and extends within a plane that is substantially identical to a plane of the base plate.

10. A pump starting method for an electronic apparatus that includes a pump-lowering parts that allows a pump to be lowered to a position that is lower than a reservoir tank, the method comprising:
lowering the pump to a position that is lower than the reservoir tank using the pump-lowering parts;
starting the pump in a state where the pump has been lowered to the position that is lower than the reservoir tank; and
returning the pump, which has been lowered the position that is lower than the reservoir tank, to an original position thereof.
